(19) United States
(12) Patent Application Publication
(10) Pub. No.: US 2014/0027729 A1
(43) Pub. Date: Jan. 30, 2014

(54) ORGANIC LIGHT EMITTING DIODE DISPLAY AND MANUFACTURING METHOD THEREOF

(71) Applicant: SAMSUNG DISPLAY CO., LTD., Yongin-City (KR)

(72) Inventors: Dong-Yoon So, Yongin-City (KR); Ji-Eun Kim, Yongin-City (KR); Han-Soo Kim, Yongin-City (KR)

(73) Assignee: SAMSUNG DISPLAY CO., LTD., Yongin-City (KR)

(21) Appl. No.: 13/758,651

(22) Filed: Feb. 4, 2013

(30) Foreign Application Priority Data
Jul. 27, 2012 (KR) 10-2012-0082697

(51) Int. Cl. H01L 51/50; H01L 51/56

(52) U.S. Cl. CPC H01L 51/5056; H01L 51/56; H01L 51/5072; H01L 51/5092; H01L 51/5088
USPC 257/40; 438/34

(57) ABSTRACT

An OLED display includes: pixel electrodes electrically connected to a thin film transistor on a substrate; a pixel defining portion including a pixel defining layer surrounding the respective pixel electrodes to define an individual pixel area, and a spacer protruding from the pixel defining layer; and a sealing substrate bonded to the substrate while maintaining a distance to the substrate by the spacer. An opaque deposition material is formed on the pixel defining portion, excluding one surface of the spacer that faces the sealing substrate, and on the pixel electrodes.

### CLAIM OF PRIORITY

This application makes reference to, incorporates the same herein, and claims all benefits accruing under 35 U.S.C. §119 from an application earlier filed in the Korean Intellectual Property Office on the 27 Jul. 2012 and there duly assigned Serial No. 10-2012-0082697.

### BACKGROUND OF THE INVENTION

1. Field of the Invention

The present invention relates generally to an organic light emitting diode (OLED) display. More particularly, the invention relates to an OLED display provided with a pixel defining layer and a spacer, and a method for manufacturing the same.

2. Description of the Related Art

An organic light emitting diode (OLED) display includes a plurality of pixels, and an organic light emitting diode (OLED) and a pixel circuit are provided in each pixel. Each pixel is distinguished from its adjacent pixel by being surrounded by a pixel defining layer. In addition, a spacer is formed on the pixel defining layer to provide a space between a sealing substrate and a substrate where an organic light emitting diode (OLED) is formed.

In general, a halfton mask is used to form the pixel defining layer and the spacer through one process. In this case, the side of the spacer has a gentle angle and the upper surface of the spacer is formed flat and wide due to a material property thereof. Thus, a contact area between the spacer and the sealing substrate is increased. In addition, the spacer is exposed to a deposition source through a deposition process after forming of the spacer so that the deposition material remains on the spacer.

When instantaneous external impact is applied to the OLED display, the substrate and the sealing substrate slide with respect to each other so that the deposition material on the spacer may be transferred at an angle to the inner side of the sealing substrate and the transferred deposition material may face the emission layer on the pixel electrode. In this case, light emitted from the emission layer is shielded by the deposition material, and thus it cannot transmit through the sealing substrate so that luminance of the corresponding pixel is deteriorated and a blur may viewed in the screen.

The above information disclosed in this Background section is only for enhancement of an understanding of the background of the described technology, and therefore it may contain information that does not form the prior art that is already known in this country to a person of ordinary skill in the art.

### SUMMARY OF THE INVENTION

The present invention has been developed in an effort to provide an OLED display that can prevent deterioration of luminance of a pixel due to external impact, and can prevent occurrence of a blur in the screen, and a method for manufacturing the same.

An OLED display according to an exemplary embodiment of the invention includes: pixel electrodes electrically connected to a thin film transistor on a substrate; a pixel defining portion including a pixel defining layer surrounding the respective pixel electrodes so as to define an individual pixel area, and a spacer protruding from the pixel defining layer; and a sealing substrate bonded to the substrate while maintaining a distance from the substrate by the spacer. An opaque deposition material is formed on the pixel defining portion, excluding one surface of the spacer that faces the sealing substrate, and on the pixel electrodes.

The opaque deposition material may be an emission layer. At least one of a hole injection layer (HIL), a hole transport layer (HTL), an electron transport layer (ETL), and an electron injection layer (EIL) may be formed on one surface of the emission layer.

The hole injection layer (HIL), the hole transport layer (HTL), the electron transport layer (ETL), and the electron injection layer (EIL) may be formed on the pixel defining portion, excluding one surface of the spacer, and on the pixel electrodes.

The OLED display may further include a common electrode that covers the emission layer, and the common electrode may be formed on the pixel defining portion, excluding one surface of the spacer, and on the pixel electrodes. The common electrode may be formed on the pixel defining portion including one surface of the spacer, and on the pixel electrodes.

The hole injection layer (HIL), the hole transport layer (HTL), the electron transport layer (ETL), and the electron injection layer (EIL) may be formed on the pixel defining portion including one surface of the spacer, and on the pixel electrodes. The common electrode may be formed on the pixel defining portion including one surface of the spacer, and on the pixel electrodes.

The pixel electrodes may be disposed in parallel with first and second directions on the substrate, and the spacer may be disposed between the pixel electrodes that are adjacent along the diagonal direction.

A method for manufacturing an OLED display according to an exemplary embodiment includes: forming pixel electrodes, a pixel defining layer, and a spacer on a substrate; forming an emission layer on the substrate by using a first deposition mask having an opening that exposes the pixel electrodes of at least one column, and a protrusion that shields the spacer; and forming at least a part of a common layer by using a second deposition mask having a blocking member that shields the spacer.

The common layer may include a hole injection layer (HIL), a hole transport layer (HTL), an electron transport layer (ETL), an electron injection layer (EIL), and a common electrode. The blocking member may include a first blocking member crossing the pixel electrodes along a first direction and a second blocking member crossing the first blocking member.

The pixel electrodes may be disposed in parallel in first and second directions on the substrate, and the spacer may be disposed between the pixel electrodes that are adjacent along the diagonal direction.

According to the present invention, the deposition material is not transferred to the inner side of the sealing substrate even if the substrate and the sealing substrate slide with respect to each other due to external impact. Therefore, luminance deterioration of a pixel and occurrence of a blur due to luminance deterioration can be prevented.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a partially enlarged cross-sectional view of an OLED display according to a first exemplary embodiment of the invention.

FIG. 2 is an enlarged view of portion “A” in FIG. 1.

FIG. 3 is a layout view of a pixel electrode and a pixel defining layer of FIG. 1.

FIG. 4 is a schematic diagram illustrating a state in which a substrate and a sealing substrate in the OLED display of FIG. 1 are deviated due to external impact.

FIG. 5 is a schematic diagram illustrating a substrate and a sealing substrate in an OLED display of a comparative embodiment in which an opaque deposition material is formed in an upper surface of a spacer.

FIG. 6 is a partially enlarged cross-sectional view of an OLED display according to a second exemplary embodiment of the invention.

FIG. 7 is a partially enlarged cross-sectional view of an OLED display according to a third exemplary embodiment of the invention.

FIG. 8A and FIG. 8B are schematic diagrams for describing a method for manufacturing an OLED display according to a fourth exemplary embodiment of the invention.

### DETAILED DESCRIPTION OF THE INVENTION

The present invention will be described more fully hereinafter with reference to the accompanying drawings, in which exemplary embodiments of the invention are shown. As those skilled in the art will realize, the described embodiments may be modified in various different ways, all without departing from the spirit or scope of the present invention.

The drawings and description are to be regarded as illustrative in nature and not restrictive. Like reference numerals designate like elements throughout the specification. Furthermore, the size and thickness of each component shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thickness of some layers and areas is exaggerated. It will be understood that, when an element such as a layer, film, region, or substrate is referred to as being “on” another element, it can be directly on the other element or intervening elements may also be present.

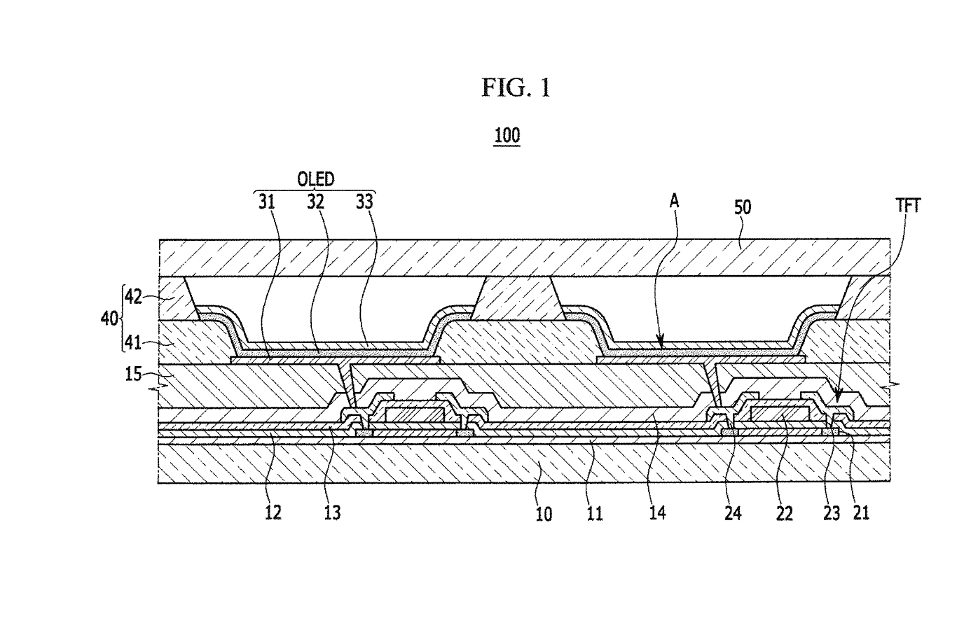

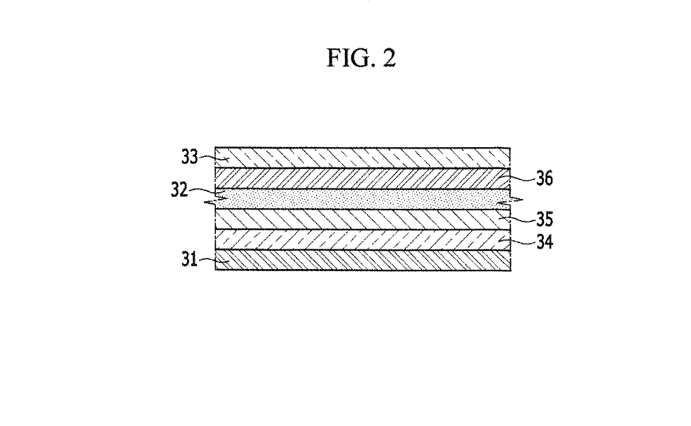

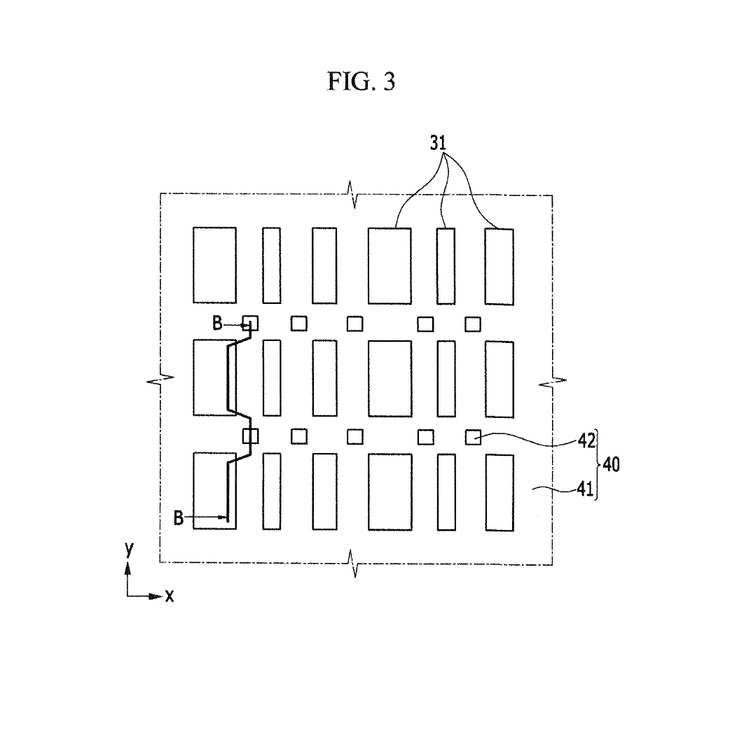

FIG. 1 is a partially enlarged cross-sectional view of an organic light emitting diode (OLED) display according to a first exemplary embodiment of the invention, FIG. 2 is an enlarged view of portion “A” of FIG. 1, and FIG. 3 is a layout view of a pixel electrode and a pixel defining layer of FIG. 1. In particular, FIG. 1 shows a cross-section cut away along the line B-B of FIG. 3.

Referring to FIG. 1 to FIG. 3, an OLED display 100 according to the first exemplary embodiment includes a substrate 10, a thin film transistor (TFT), a pixel defining portion 40, an organic light emitting diode OLED, and a sealing substrate 50.

The substrate 10 is formed of glass or plastic film, and a buffer layer 11 is disposed on the substrate 10. The thin film transistor TFT, including an active layer 21, a gate electrode 22, a source electrode 23, and a drain electrode 24, is disposed on the buffer layer 11.

The active layer 21 includes a channel area, a source area, and a drain area, and a gate insulating layer 12 is disposed on the active layer 21. The gate electrode 22 is formed on the gate insulating layer 12 of the channel area, and an interlayer insulating layer 13 covers the gate electrode 22. The source electrode 23 and the drain electrode 24 are disposed on the interlayer insulating layer 13, and the source electrode 23 and the drain electrode 24 are connected to the source area and the drain area, respectively, through a contact hole of the interlayer insulating layer 13.

A passivation layer 14 is formed on the source electrode 23 and the drain electrode 24, and a planarization layer 15 is disposed on the passivation layer 14. The passivation layer 14 may be formed of an inorganic material such as SiO₂, SiNₓ, and the like, and the planarization layer 15 may be formed of an organic material such as polyimide, benzocyclobutane, and the like. A pixel electrode 31 is formed on the planarization layer 15. The pixel electrode 31 is connected to the drain electrode 24 through via holes of the planarization layer 15 and the passivation layer 14. The pixel electrode 31 is formed in each pixel, and may be formed of a metal having high light reflection efficiency.

The pixel defining portion 40 is disposed on the pixel electrode 31 and the planarization layer 15. The pixel defining portion 40 includes a pixel defining layer 41 forming a boundary with a neighboring pixel by surrounding each pixel area, and a spacer 42 protruding from the pixel defining layer 41. The pixel defining layer 41 forms an opening that wholly or partially exposes the pixel electrode 31. The pixel defining layer 41 and the spacer 42 may be formed through a single process using a half-tone mask.

Pixel electrodes 31 of the respective pixels may be formed with the same size regardless of the color of a light emission layer 32, or may be formed with different sizes according to the color of the light emission layer 32. The spacer 42 is partially formed on the pixel defining layer 41, and may be disposed between adjacent pixel electrodes 31 along a first direction (i.e., x-axis direction) or a second direction (i.e., y-axis direction) or between adjacent pixel electrodes 31 along a diagonal direction.

FIG. 2 exemplarily illustrates that the pixel electrodes 31 are formed with different sizes according to the color of the light emission layer 32, and the spacer 42 is disposed between adjacent pixel electrodes 31 along a diagonal direction. In this case, the diagonal direction implies a direction having a predetermined angle with the first direction (x-axis direction) and the second direction (y-axis direction).

When the spacers 42 of FIG. 1 are disposed between the pixel electrodes 31 adjacent along the diagonal direction, the light emission layer 32 and a common layer can be easily prevented from being formed on one side of the spacer 42 facing the sealing substrate 50, that is, an upper surface of the spacer 42 in a manufacturing process of the OLED display 100. The size of the pixel electrode 31 and the location and shape of the spacer 42 are not limited to those shown in FIG. 2, and may be variously modified.

The light emission layer 32 is formed on the pixel electrode 31. The emission layer 32 is one of a red emission layer, a green emission layer, and a blue emission layer, and the red emission layer, the green emission layer, and the blue emission layer may be sequentially disposed on the pixel electrodes 31 disposed along the first direction (x-axis direction). In addition, a common electrode 33 is disposed on the emission layer 32. The common electrode 33 covers the plurality of pixel electrodes 31, and may be formed of a transparent conductive layer (e.g., an indium tin oxide layer or an indium zinc oxide layer). The pixel electrode 31, emission layer 32, and common electrode 33 form an organic light emitting diode OLED.

The pixel electrode 31 may be an anode that injects holes into the emission layer 32, and the common electrode 33 may be a cathode that injects electrons into the emission layer 32. In this case, at least one of a hole injection layer (HIL) and a hole transport (HTL) layer may be formed for improving light emission efficiency of the emission layer 32. In addition, at least one of an electron transport layer (ETL) and an electron injection layer (EIL) may be formed between the emission layer 32 and the common electrode 33.

FIG. 2 exemplarily illustrates that a hole injection layer (HIL) 34 and a hole transport layer (HTL) 35 are disposed between the pixel electrode 31 and the emission layer 32, and an electron transport layer (ETL) 36 is disposed between the emission layer 32 and the common electrode 33. The hole injection layer (HIL) 34, the hole transport layer (HTL) 35, the electron transport layer (ETL) 36, and the common electrode 33 are commonly formed over at least two pixel electrodes 31 without performing pixel-specific patterning. Hereinafter, the hole injection layer (HIL) 34, the hole transport layer (HTL) 35, the electron transport layer (ETL) 36, and the common electrode 33 will be referred to as common layers for convenience in description.

The sealing substrate 50 of FIG. 1 is attached onto the substrate 10 by a sealant (not shown), and seals a display area using the sealant to protect the display area from external moisture and oxygen. The sealing substrate 50 is foamed of a glass or plastic film, or is formed of a transparent material. Since the spacer 42 is disposed in the uppermost portion on the substrate 10, the spacer 42 contacts the sealing substrate 50 when the substrate 10 and the sealing substrate 50 are bonded to each other so that a gap between the substrate 10 and the sealing substrate 50 can be maintained.

When a current flows to the organic light emitting diode (OLED) through the thin film transistor (TFT), the emission layer 32 emits light with luminance that corresponds to the amount of the supplied current. In this case, the pixel electrode 31 is reflective, the common electrode 33 and the sealing substrate 50 are transmissive, and light emitted from the emission layer 32 is passed through the common electrode 33 and the sealing substrate 50 and is then emitted to the outside. When a material blocking light exists in an inner side of the sealing substrate 50 on a path of light that passes through the sealing substrate 50, luminance of the corresponding pixel is deteriorated and a stain may be viewed in the screen.

Both an opaque deposition material and a transparent deposition material do not exist on one surface (for convenience, referred to as an upper surface of the spacer) of the spacer 42 that faces the sealing substrate 50. In this case, the opaque deposition material may be the emission layer 32, and the transparent deposition material may be the common layer. At least one of the hole injection layer (HIL) 34, the hole transport layer (HTL) 35, the electron transport layer (ETL) 36 and the common electrode 33 forming the common layer may have a light color, but the least one layer is assumed to be the transparent deposition material because transparency is relatively higher than the emission layer 32.

The emission layer 32 and the common layer are disposed on the pixel defining portion 40, excluding the above of the pixel electrode 31 and the upper surface of the spacer 42. That is, layers (i.e., the emission layer 32 and the common layer) deposited after the spacer 42 are not disposed in the upper surface of the spacer 42, and the upper surface of the spacer 42 is directly exposed to the sealing substrate 50. Thus, the sealing substrate 50 directly contacts the upper surface of the spacer 42 when the substrate 10 and the sealing substrate 50 are bonded to each other.

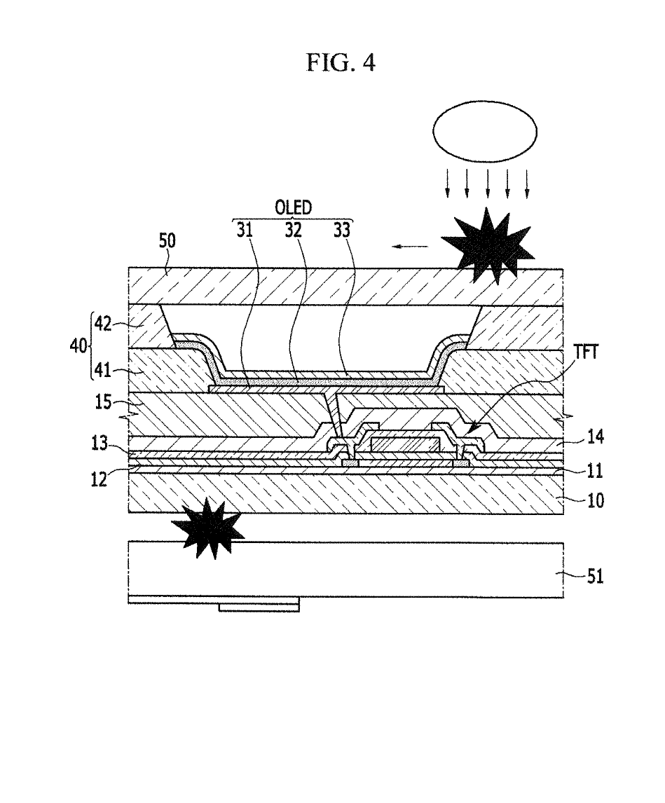

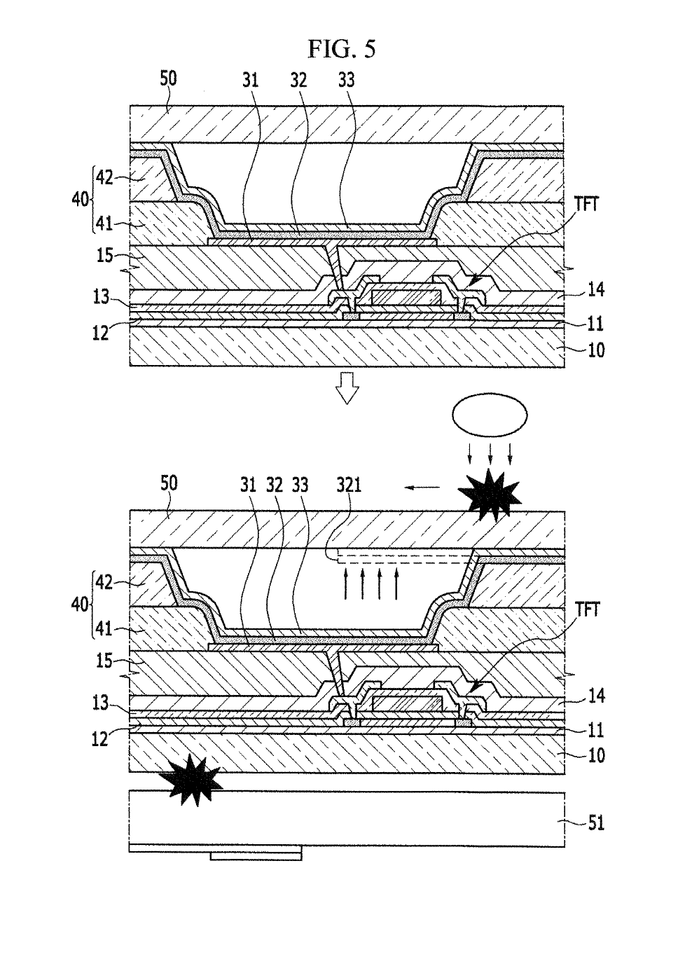

FIG. 4 is a schematic diagram illustrating a state in which a substrate and a sealing substrate in the OLED display of FIG. 1 are deviated due to external impact, and FIG. 5 is a schematic diagram illustrating a substrate and a sealing substrate in an OLED display of a comparative embodiment in which an opaque deposition material is formed in an upper surface of a spacer.

Referring to FIG. 4 and FIG. 5, when instantaneous external impact is applied to the OLED display from the outside of the substrate 10 or the outside of the sealing substrate 50, the substrate 10 and the sealing substrate 50 may slide with respect to each other. In FIG. 4 and FIG. 5, reference numeral 51 indicates a structure such as a bracket and a flexible printed circuit board (PCB).

In a comparative example (FIG. 5), a deposition material (i.e., emission layer 321) is formed between a spacer 42 and a sealing substrate 50. In this case, an opaque deposition material on the spacer 42 is transferred at an angle to an inner side of the sealing substrate 50 due to displacement of the sealing substrate 50. The opaque deposition material transferred to the sealing substrate 50 faces the emission layer 321 on a pixel electrode 31 so that light emitted from the emission layer 321 is blocked. Thus, luminance of a specific pixel is deteriorated and a failure in visibility occurs because the pixel is viewed as a blur in the screen in the comparative example.

However, in the OLED display (FIG. 4) of the first exemplary embodiment, no deposition material exists between the spacer 42 and the sealing substrate 50, and therefore deposition material is not transferred to the inner side of the sealing substrate 50 even through displacement occurs in the sealing substrate 50. Therefore, deterioration of luminance of pixels can be prevented, and accordingly occurrence of a blur can be prevented in the OLED display 100 according to the first exemplary embodiment.

The emission layer 32 and the common layer in the OLED display 100 can be formed using a deposition mask manufactured to shield the spacer 42. A method for manufacturing the OLED display 100 will be described later.

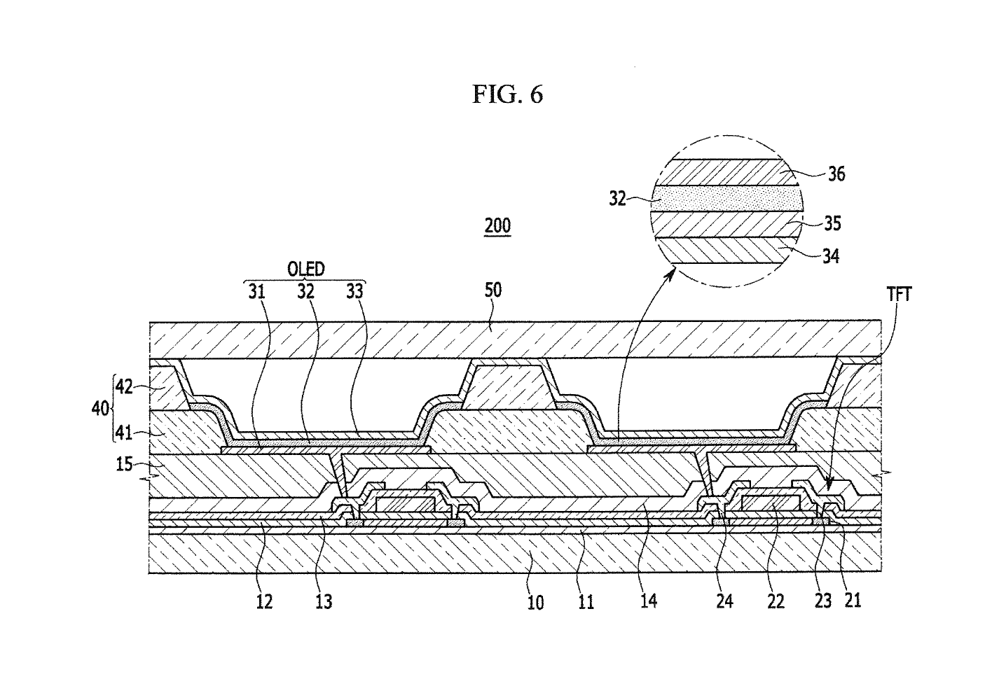

FIG. 6 is a partially enlarged cross-sectional view of an OLED display according to a second exemplary embodiment of the invention.

Referring to FIG. 6, an OLED display 200 according to the second exemplary embodiment is the same as the OLED display of the first exemplary embodiment except that a part of a common layer, that is, a common electrode 33, is formed over the entire area of a display area. In the second exemplary embodiment, the same reference numerals refer to the same members as in the first exemplary embodiment.

An emission layer 32 and a common layer (i.e., a hole injection layer 34, a hole transfer layer 35, and an electron transfer layer 36), excluding a common electrode 33, are disposed on a pixel electrode 31 and on a pixel defining portion 40, excluding an upper surface of a spacer 42. In addition, the common electrode 33 is disposed over the entire display area including the upper surface of the spacer 42.

Since the common electrode 33 is formed as a transparent conductive layer that transmits light, displacement occurs in the sealing substrate 50 due to external impact so that a common electrode material transferred to the sealing substrate 50 does not block light of the emission layer 32 even through the common electrode material is transferred to the inner side of the sealing substrate 50. Thus, luminance deterioration of specific pixels can be prevented, and accordingly generation of a blur can be prevented.

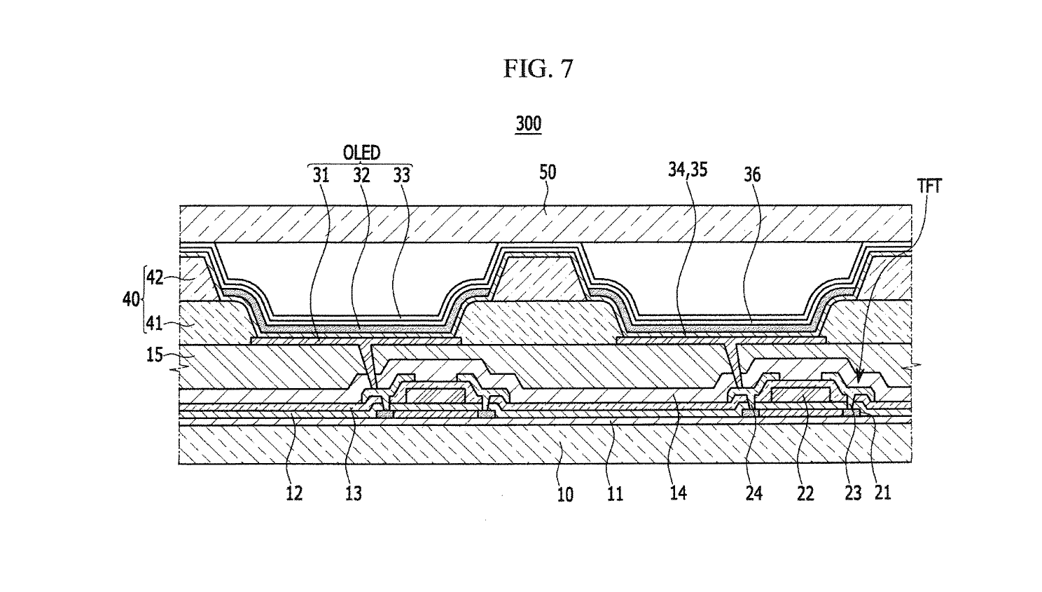

FIG. 7 is a partially enlarged cross-sectional view of an OLED display according to a third exemplary embodiment of the invention.

Referring to FIG. 7, an OLED display 300 according to a third exemplary embodiment is the same as the OLED display of the first exemplary embodiment, except that a common layer is formed over the entire display area. In the third exemplary embodiment, the same reference numerals refer to the same members as in the first exemplary embodiment.

An emission layer 32 is disposed on a pixel electrode 31 and a pixel defining portion 40, excluding an upper surface of a spacer 42. On the other hand, a common electrode (i.e., a hole injection layer (HIL) 34, a hole transport layer (HTL) 35, an electron transport layer (ETL) 36, and a common electrode 33) is disposed in the entire display area including the upper surface of the spacer 42.

A part of the common electrode may have a light color, but basically has high transmittance. Thus, although the sealing substrate 50 experiences displacement due to external impact, and thus a common layer material is transferred to the inner surface of the sealing substrate 50, an observer can hardly recognize luminance deterioration caused by the common layer material. As a result, as in the previous exemplary embodiments, luminance deterioration of specific pixels and generation of a blur caused by the luminance deterioration can be prevented.

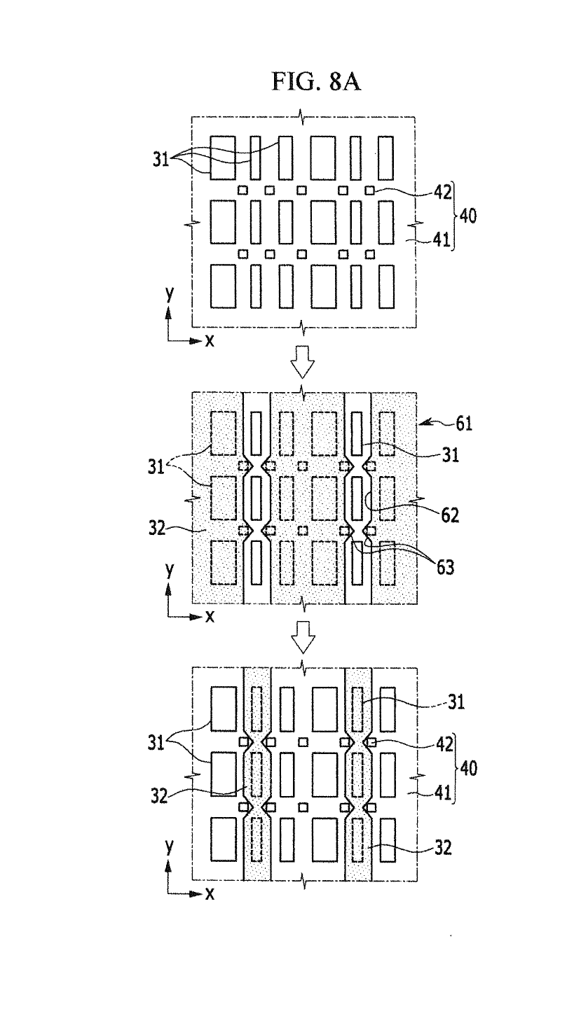

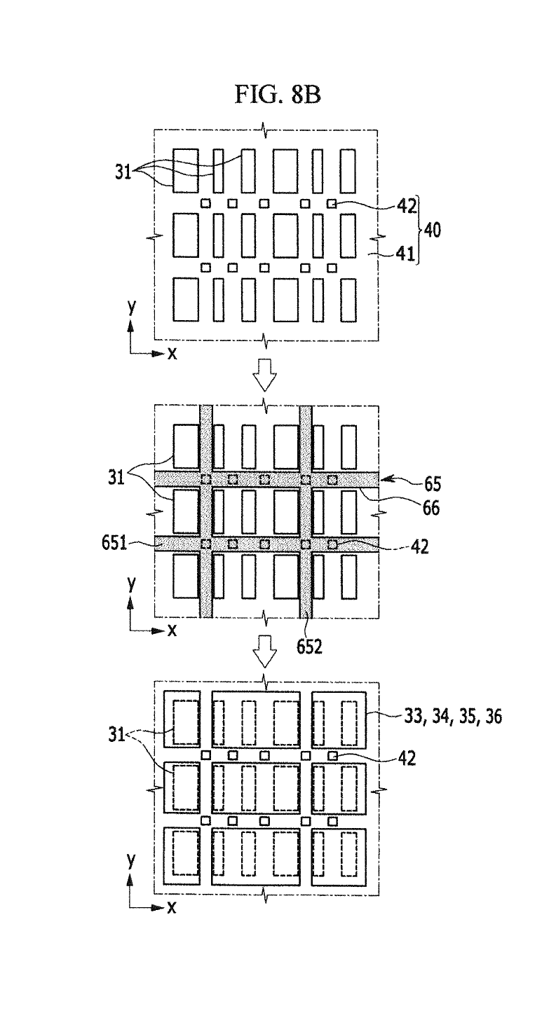

FIG. 8A and FIG. 8B are schematic diagrams for describing a method for manufacturing an OLED display according to a fourth exemplary embodiment of the invention. A process for forming the thin film transistor, the pixel electrode, and the pixel defining portion on the substrate is the same as a known OLED display, and therefore, no further description will be provided. Hereinafter, a process for manufacturing an emission layer and a common layer will be described.

Referring to FIG. 8A, pixel electrodes 31 are disposed in parallel with a first direction (x-axis direction) and a second direction (y-axis) direction on a substrate, and a spacer 42 is disposed between pixels 31 that are adjacent along a diagonal direction. The diagonal direction implies a direction having a predetermined angle with respect to the first direction and the second direction.

A first deposition mask 61 is mounted on the substrate where the pixel electrodes 31 and a pixel defining portion 40 are formed. The first deposition mask 61 is formed to provide an emission layer 32, and forms an opening 62 that is parallel with the second direction so as to expose pixel electrodes 31 of the corresponding column. In this case, a protrusion 63 that shields the spacer 42 is formed in the first deposition mask 61 so that the spacer 42 can be prevented from being exposed to a deposition source (not shown). FIG. 8A exemplarily illustrates that the protrusion 63 is formed in the shape of a triangle, but the shape of the protrusion 63 is not limited thereto.

A material emitted from the deposition source is deposited on a portion exposed by the opening 62 of the first deposition mask 61, that is, on the pixel electrodes 31 along the second direction, and on a pixel defining portion 40 excluding the spacer 42 so that an emission layer 32 of a specific color is formed. An emission layer 32 that is an opaque deposition material is not deposited on the upper surface of the spacer 42 due to the protrusion 63 of the first deposition mask 61. With such a method, emission layers of two different colors are formed using the first deposition mask 61 having the protrusion 63.

Meanwhile, when the spacer is disposed between pixel electrodes that are adjacent to each other along the second direction and a deposition mask having an opening that is parallel with the second direction formed therein, the spacers are exposed to the deposition source by the opening of the deposition mask. Thus, the emission layer is deposited on the upper surface of the spacer, and the emission layer on the upper surface of the spacer may be transferred at an angle to an inner side of a sealing substrate when the substrate and the sealing substrate slide with respect to each other due to external impact (refer to FIG. 5).

Referring to FIG. 8B, a second deposition mask 65 is mounted on the substrate. The second deposition mask 65 forms a common layer, and includes blocking members 651 and 652 that shield the spacer 42. The common layer may include a hole injection layer (HIL) 34, a hole transport layer (HTL) 35, an electron transport layer (ETL) 36, and a common electrode 33. The hole injection layer (HIL) 34 and the hole transport layer (HTL) 35 are formed before the emission layer 32 is formed, and the electron transport layer (ETL) 36 and the common electrode 33 are formed after the emission layer 32 is formed.

The blocking members 651 and 652 may be formed of a first blocking member 651 that crosses between pixel electrodes 31 along the first direction (x-axis direction) and a second blocking member 652 that crosses the first blocking member 651. In this case, the common layer is selectively formed only in a portion of the substrate exposed by an opening 66 that is surrounded by the first and second blocking members 651 and 652, and the common layer is not formed on the upper surface of the spacer 42.

Since the common electrode 33 is divided into plural portions when the common electrode 33 is formed using the second deposition mask 65, a connection layer (not shown) may be additionally formed for connection between the separated common electrodes 33.

As described, the deposition material can be prevented from remaining in the upper surface of the spacer 42 by forming the protrusion 63 of FIG. 8A or the blocking members 651 and 652 of FIG. 8B shielding the spacer 42 of FIG. 8A and 8B in the first deposition mask 61 of FIG. 8A or the deposition mask 65 of FIG. 8B, respectively.

In the OLED display 100 of the first exemplary embodiment of FIG. 1, the common layers 34, 35, 36, and 33 are formed by using the second deposition mask 65 of FIG. 8B. In the OLED display 200 of the second exemplary embodiment of FIG. 6, the common electrode 33 is formed using an open mask (not shown) that does not include a blocking member, and the hole injection layer (HIL) 34, the hole transport layer (HTL) 35, and the electron transport layer (ETL) 36 are formed using the second deposition mask 65 of FIG. 8B. In the OLED display 300 of the third exemplary embodiment of FIG. 7, the common electrodes 34, 35, 36, and 33 are formed using an open mask that does not include a blocking member.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An organic light emitting diode (OLED) display device, comprising:
pixel electrodes electrically connected to a thin film transistor on a substrate;
a pixel defining portion including a pixel defining layer surrounding the respective pixel electrodes to define an individual pixel area, and a spacer protruding from the pixel defining layer; and
a sealing substrate bonded to the substrate while maintaining a distance to the substrate by means of the spacer;
an opaque deposition material being formed on the pixel defining portion, excluding one surface of the spacer that faces the sealing substrate, and on the pixel electrodes.

2. The OLED display device of claim 1, the opaque deposition material being an emission layer.

3. The OLED display device of claim 2, at least one of a hole injection layer, a hole transport layer, an electron transport layer, and an electron injection layer being formed on said one surface of the emission layer.

4. The OLED display device of claim 3, said at least one of the hole injection layer, the hole transport layer, the electron transport layer, and the electron injection layer being formed on the pixel defining portion, excluding one surface of the spacer, and on the pixel electrodes.

5. The OLED display device of claim 4, further comprising a common electrode that covers the emission layer, the common electrode being formed on the pixel defining portion, excluding one surface of the spacer, and on the pixel electrodes.

6. The OLED display device of claim 4, further comprising a common electrode covering the emission layer, the common electrode being formed on the pixel defining portion including one surface of the spacer, and on the pixel electrodes.

7. The OLED display device of claim 3, said at least one of the hole injection layer, the hole transport layer, the electron transport layer, and the electron injection layer being formed on the pixel defining portion including one surface of the spacer, and on the pixel electrodes.

8. The OLED display device of claim 7, further comprising a common electrode covering the emission layer, the common electrode being formed on the pixel defining portion including one surface of the spacer, and on the pixel electrodes.

9. The OLED display device of claim 2, at least one of a hole injection layer, a hole transport layer, an electron transport layer, and an electron injection layer being formed on the pixel defining portion, excluding one surface of the spacer, and on the pixel electrodes.

10. The OLED display device of claim 9, further comprising a common electrode that covers the emission layer, the common electrode being formed on the pixel defining portion, excluding one surface of the spacer, and on the pixel electrodes.

11. The OLED display device of claim 9, further comprising a common electrode covering the emission layer, the common electrode being formed on the pixel defining portion including one surface of the spacer, and on the pixel electrodes.

12. The OLED display device of claim 2, at least one of a hole injection layer, a hole transport layer, an electron transport layer, and an electron injection layer being formed on the pixel defining portion, including one surface of the spacer, and on the pixel electrodes.

13. The OLED display device of claim 12, further comprising a common electrode covering the emission layer, the common electrode being formed on the pixel defining portion including one surface of the spacer, and on the pixel electrodes.

14. The OLED display device of claim 1, the pixel electrodes being disposed in parallel with first and second directions on the substrate, and the spacer being disposed between the pixel electrodes that are adjacent along a diagonal direction.

15. A method for manufacturing an organic light emitting diode (OLED) display device, comprising the steps of:
forming pixel electrodes, a pixel defining layer, and a spacer on a substrate;
forming an emission layer on the substrate by using a first deposition mask having an opening that exposes the pixel electrodes of at least one column and a protrusion that shields the spacer; and
forming at least a part of a common layer by using a second deposition mask having a blocking member that shields the spacer.

16. The method for manufacturing the OLED display device of claim 15, the common layer comprising a hole injection layer, a hole transport layer, an electron transport layer, an electron injection layer, and a common electrode.

17. The method for manufacturing the OLED display device of claim 15, the blocking member comprising a first blocking member crossing the pixel electrodes along a first direction and a second blocking member crossing the first blocking member.

18. The method for manufacturing the OLED display device of claim 15, the pixel electrodes being disposed in parallel with first and second directions on the substrate, and the spacer being disposed between the pixel electrodes that are adjacent along a diagonal direction.
